(19) United States
(12) Patent Application Publication
(10) Pub. No.: US 2008/0293173 A1
(43) Pub. Date: Nov. 27, 2008

(54) White Multi-Wavelength LED and Its Manufacturing Process

(76) Inventor: Ming-Shun LEE, Taipei (TW)

Correspondence Address: TROXELL LAW OFFICE PLLC, SUITE 1404, 5205 LEESBURG PIKE, FALLS CHURCH, VA, 22041, US

(21) Appl. No.: 12/186,901

(22) Filed: Aug. 6, 2008

Related U.S. Application Data
(62) Division of application No. 11/245,202, filed on Oct. 7, 2005.

(51) Int. Cl. H01L 33/00

(52) U.S. Cl. 438/27; 257/E33.061

(57) ABSTRACT

A white multi-wavelength LED and its manufacturing process has bonded at the bottom of a light emitting chip in a given color a first non-conductive material containing phosphor in a corresponding color to that of the chip to become a die unit; the first non-conductive material functioning as the position where the die unit is bonded to a carrier; golden plated wire constituting the circuit connection of the chip; a second non-conductive material containing phosphor in a color corresponding to that of the chip being injected to cover up the top of the chip to emit the expected white light and effectively promote the luminance performance of the LED.

### BACKGROUND OF THE INVENTION

(a) Field of the Invention

The present invention is related to a white multi-wavelength light emitting diode (LED), and more particularly to a light emitting diode that emits light of correct color and effectively promotes the performance of luminance, and a manufacturing process of the LED.

(b) Description of the Prior Art

Usually a light emitting diode is comprised of having a packaging material (non-conductive material) to wrap up a light emitting integrated circuit (IC), and a golden wire to connect IC electrodes to the circuit so that once the IC is conducted, it emits the light to outwardly irradiate through the packaging material, and the light emitted from the chip is further incorporated with the wavelength of a non-conductive material in the packaging material to emit the light in an expected color.

As illustrated in FIG. 1 of the accompanying drawings of the present invention, a while LED construction of the prior art has a bowl shaped carrier 10 to secure a blue light emitting chip 21 and accommodate a packaging material 30, an encapsulating material 40 is coated at where between the blue light emitting chip 21 and the carrier (or a similar substrate) to secure the chip 21. In practice, the light emitted from the chip 21 is incorporated with the wavelength of a yellow phosphor 51 in the packaging material 30 to produce white light; or alternatively as illustrated in FIG. 2, the light emitted from the chip 21 is incorporated with the wavelength of a red phosphor 52 and that of a green phosphor 53 to produce white light. Furthermore, in another prior art yet, the encapsulating material is used to secure a blue light emitting chip in a carrier while gold plated wire is used to connect between the, chip and electrodes so that once the chip is conducted, the phosphor is excited by the light from the blue light emitting chip to produce the light in a color as desired.

Therefore, to produce white light from the white LED, it takes to allow the light emitting chip in a given color to be incorporated with the wavelength of a phosphor in a color corresponding to that of the chip. However, the construction of a white LED illustrated in FIG. 1 of having an encapsulating material 40 directly embedded at the bottom of a blue light emitting chip 21, the light travel or the extent of the phosphor is excited may vary depending on the level of the encapsulating material 40 is embedded, thus to compromise the luminance and color performance of the entire LED.

### SUMMARY OF THE INVENTION

The primary purpose of the present invention is to provide a white multi-wavelength LED to produce the expected white light and effectively promote luminance performance. To achieve the purpose, a die unit for a white multi-wavelength LED is comprised of having at the bottom of a light emitting chip in a given color bonded with a first non-conductive material containing phosphor in a color corresponding to that of the chip. The first non-conductive material functions as the position to coat the encapsulating material to secure the die unit to the carrier. Golden plated wire is used as circuit connection for the light emitting chip, and finally, a second non-conductive material containing phosphor in a color corresponding to that of the chip is injected to cover up the light emitting chip to allow the light from the chip to pass through both of the first and the second non-conductive materials and to be incorporated with the wavelength of the phosphor respectively contained in both of the first and the second non-conductive materials.

In practice, a blue light emitting chip is used for the entire white multi-wavelength LED. A red phosphor is mixed in the first non-conductive material, and a green phosphor is mixed in the second non-conductive material; or alternatively, an approximate ultraviolet light emitting chip is used, and a red phosphor is mixed in the first non-conductive material, and a green phosphor and a blue phosphor are mixed in the second non-conductive material.

A reflection material may be further disposed at the bottom of the first non-conductive material to help promote the luminance performance of the LED.

### BRIEF DESCRIPTION OF THE DRAWINGS

FIG. 1 is a sectional view of a white LED of the prior art.

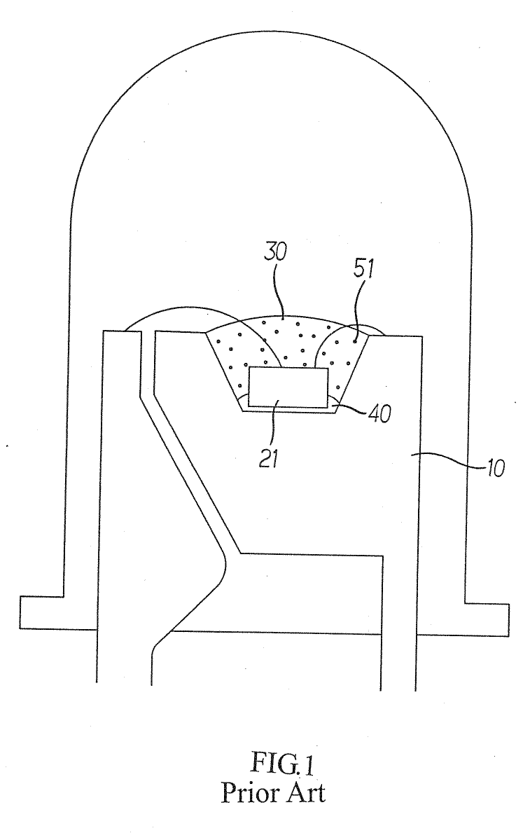

FIG. 2 is a sectional view of another white LED of the prior art.

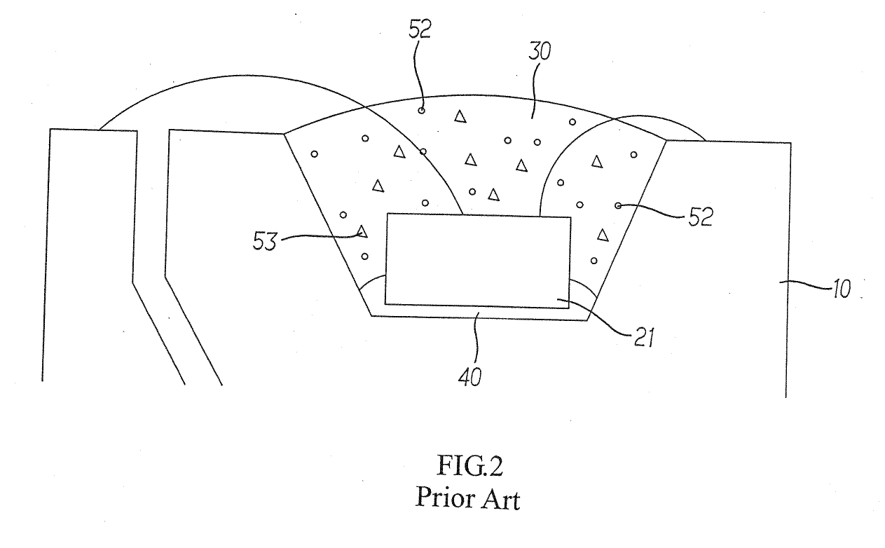

FIG. 3 is a schematic view showing an appearance of a die unit used in the prevent invention.

FIG. 4 is a sectional view of a preferred embodiment of a first type of construction of the present invention.

FIG. 5 is a sectional view of another preferred embodiment of the first type of construction of the present invention.

FIG. 6 is a sectional view of a preferred embodiment of a second type of construction of the present invention.

FIG. 7 is a sectional view of another preferred embodiment yet of the present invention.

FIG. 8 is a manufacturing process flow chart of the first type construction of the present invention.

FIG. 9 is a manufacturing process flow chart of the second type construction of the present invention.

### DETAILED DESCRIPTION OF THE PREFERRED EMBODIMENTS

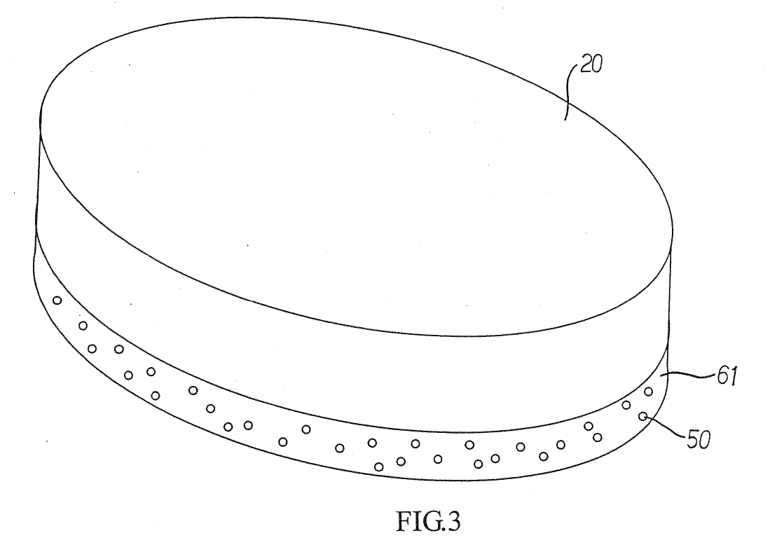

Referring to FIG. 3, a preferred embodiment of the present invention is essentially having fixed at the bottom of a light emitting chip 20 in a given color a first non-conductive material 61 containing a phosphor 50 in a color corresponding to that of the chip 20. The first non-conductive material 61 is bonded to the bottom of the chip 20 either by the spin coating or baking solidification method to form a die unit for the manufacturing of a white multi-wavelength LED of the present invention.

Accordingly, the first non-conductive material serves as the position for coating an encapsulating material to secure the die unit onto a carrier. A golden plated wire connects the circuit of the light emitting chip 20 and finally a second no-conductive material containing a phosphor in a color corresponding to that of the chip 20 is injected to cover up the top of the chip 20 to allow light from the chip 20 to pass through both of the first and the second non-conductive materials to be incorporated with the wavelength respectively from both of the first and the second no-conductive materials for producing the expected white light and effectively promoting the luminance performance of the white multi-wavelength LED.

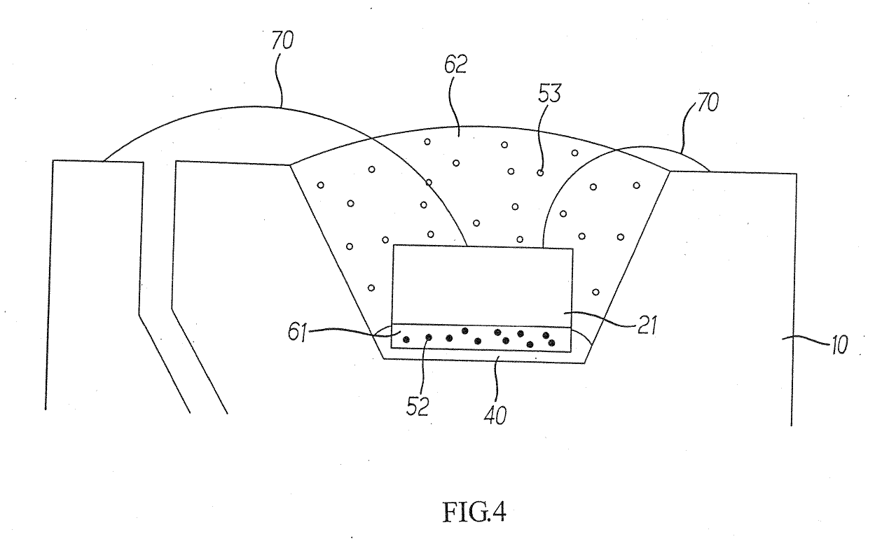

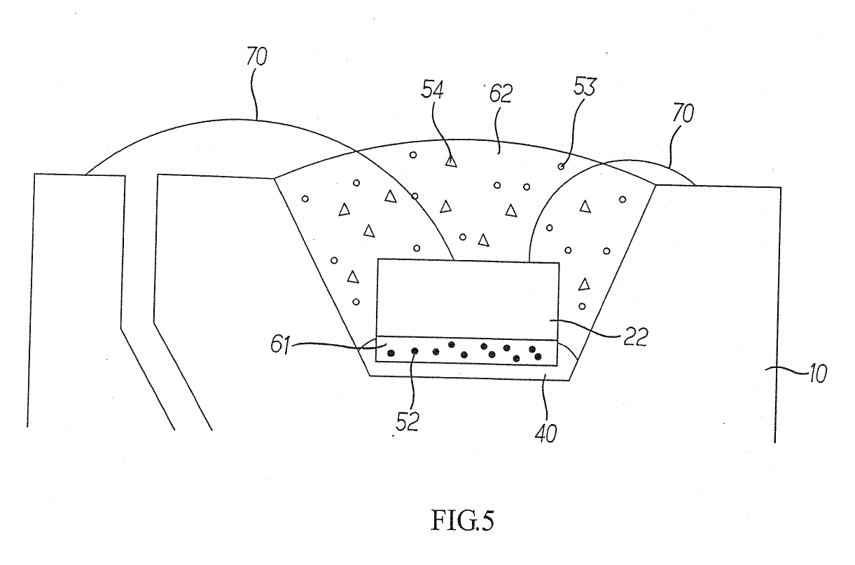

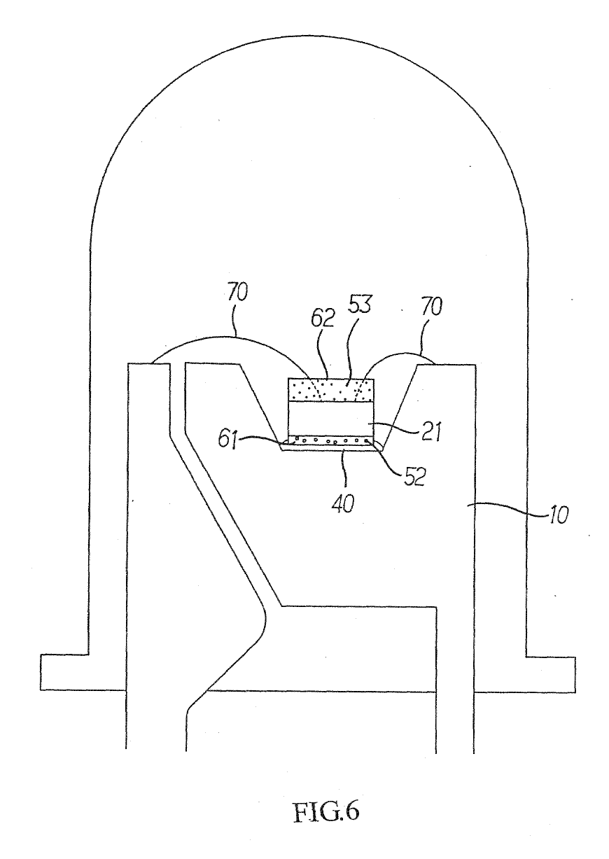

In practice, the white multi-length of the present invention is made in a first type of construction as illustrated in FIGS. 4 and 5, or in a second type of construction as illustrated in FIG. 6. In the first type of construction, a layer of the first non-conductive material containing a red phosphor 52 is bonded at the bottom of a blue light emitting chip 21 to form a die unit for the manufacturing of the white multi-wavelength LED. The first non-conductive material 61 serves as the position to coat an encapsulating material 40 to secure the die unit onto a carrier 10 while a golden plated wire 70 constitutes the circuit connection for the blue light emitting chip 21. Finally, a second non-conductive material 62 containing a green phosphor 53 is injected to cover up the top of the blue light emitting chip 21.

Furthermore, in a second preferred embodiment of the first type of construction as illustrated in FIG. 5, the first non-conductive material 61 containing the red phosphor 52 is bonded to the bottom of an approximate ultraviolet light emitting chip 22 to form a die unit for the manufacturing of the white multi-wavelength LED. With the first non-conductive material 61 as the position to coat the encapsulating material 40, the die unit is secured onto the carrier 10 while the golden plated wire constitutes the circuit connection for the approximate ultraviolet light emitting chip 22. Finally, a second non-conductive material 62 containing green phosphor 53 and blue phosphor is injected to cover up the top of the approximate ultraviolet light emitting chip 22.

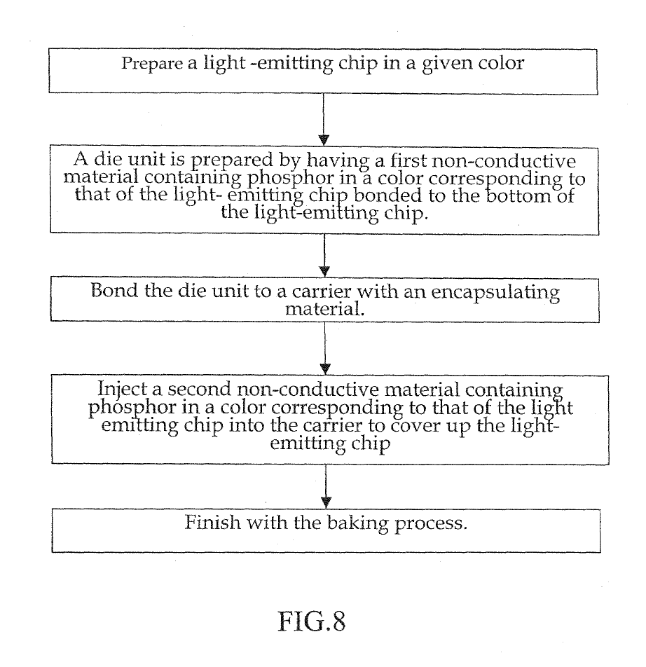

Accordingly, a manufacturing process as illustrated in FIG. 8 for the manufacturing the white multi-wavelength LED in the first type of construction includes but not limited to the following steps:
a. Prepare a light emitting chip in a given color;
b. A die unit is prepared by having a first non-conductive material containing phosphor in a color corresponding to that of the light emitting chip bonded to the bottom of the light emitting chip;
c. Bond the die unit to a carrier with an encapsulating material;
d. Inject a second non-conductive material containing phosphor in a color corresponding to that of the light emitting chip into the carrier to cover up the light emitting chip;
e. Finish with the baking process.

Furthermore, as illustrated in FIG. 6 for the second type of construction of the white multi-wavelength LED, the first non-conductive material 61 containing red phosphor 52 is bonded to the bottom of the blue light emitting chip 21 and the second non-conductive material containing green phosphor 53 is bonded to the top of the blue light emitting chip 21 to form a die unit for the manufacturing of the white multi-wavelength LED. With the first non-conductive material 61 as the position for the coating of the encapsulating material 40, the die unit is secured onto the carrier while the golden plated wire 70 constitutes the circuit connection for the blue light emitting chip 21.

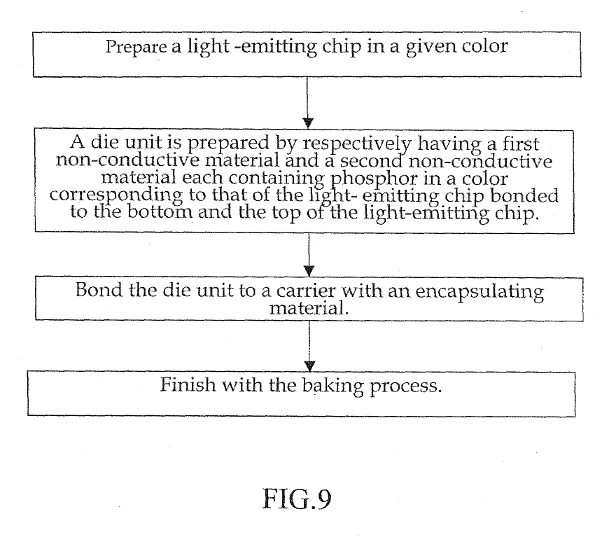

Accordingly, a manufacturing process as illustrated in FIG. 9 for the manufacturing the white multi-wavelength LED in the second type of construction illustrated in FIG. 6 includes but not limited to the following steps:
a. Prepare a light emitting chip in a given color;
b. A die unit is prepared by having a first non-conductive material containing phosphor in a color corresponding to that of the light emitting chip bonded to the bottom of the light emitting chip, a second non-conductive material containing phosphor in a color corresponding to that of the light emitting chip bonded to the top of the light emitting chip;
c. Bond the die unit to a carrier with an encapsulating material; and
d. Finish with the baking process.

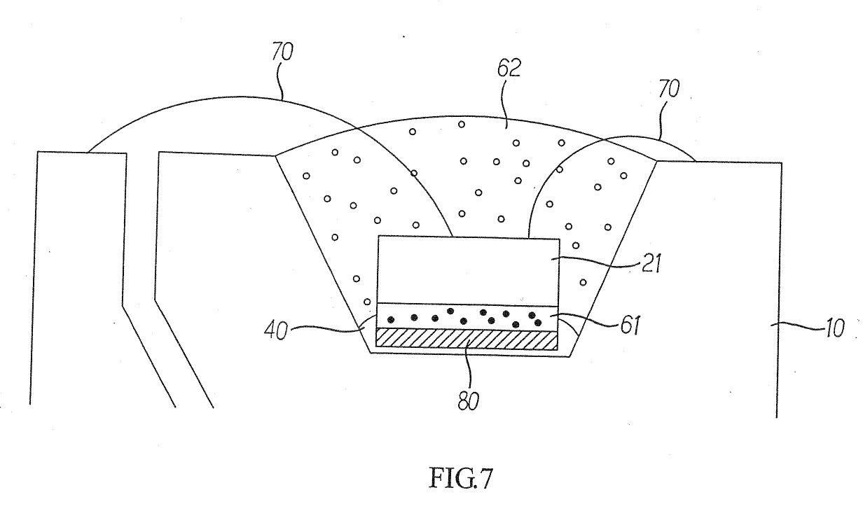

In either type of construction, the white multi-wavelength LED of the present invention entirely prevents the light emitting chip from being screened by the encapsulating material to permit the light from the light emitting chip to pass through both of the first and the second non-conductive materials without barriers and to be incorporated with the wavelength respectively from both of the first and the second non-conductive materials thus to produce the expected white light while effectively promoting the luminance performance. As illustrated in FIG. 7, a reflective material 80 is disposed at the bottom of the first non-conductive material 61 to help promote the luminance performance of the LED.

The prevent invention provides a white multi-wavelength LED structure and its related manufacturing process that generates correct white light color and effectively promotes luminance performance, and the application for a patent is duly filed accordingly. However, it is to be noted that the preferred embodiments disclosed in the specification and the accompanying drawings are not limiting the present invention; and that any construction, installation, or characteristics that is same or similar to that of the present invention should fall within the scope of the purposes and claims of the present invention.

1-7. (canceled)

8. A white multi-wavelength LED manufacturing process includes the following steps.
a. Prepare a light emitting chip in a given color;
b. A die unit is prepared by having a first non-conductive material containing phosphor in a color corresponding to that of the light emitting chip bonded to the bottom of the light emitting chip;
c. Bond the die unit to a carrier with an encapsulating material;
d. Inject a second non-conductive material containing phosphor in a color corresponding to that of the light emitting chip into the carrier to cover up the light emitting chip;
e. Finish with the baking process.

9. A white multi-wavelength LED manufacturing process includes the following steps:
a. Prepare a light emitting chip in a given color;
b. A die unit is prepared by having a first non-conductive material containing phosphor in a color corresponding to that of the light emitting chip bonded to the bottom of the light emitting chip, a second non-conductive material containing phosphor in a color corresponding to that of the light emitting chip bonded to the top of the light emitting chip;
c. Bond the die unit to a carrier with an encapsulating material with an encapsulating material; and
d. Finish with the baking process.

10. The white multi-wavelength LED manufacturing process of claim 8, wherein the light emitting chip relates to a blue light emitting chip, red phosphor is mixed into the first non-conductive material, and green phosphor is mixed into the second non-conductive material.

11. The white multi-wavelength LED manufacturing process of claim 9, wherein the light emitting chip relates to a blue light emitting chip, red phosphor is mixed into the first non-conductive material, and green phosphor is mixed into the second non-conductive material.

12. The white multi-wavelength LED manufacturing process of claim 8, wherein the light emitting chip relates to an approximate ultraviolet light emitting chip, red phosphor is mixed into the first non-conductive material, and green phosphor and blue phosphor are mixed into the second non-conductive material.

13. The white multi-wavelength LED manufacturing process of claim 9, wherein the light emitting chip relates to an approximate ultraviolet light emitting chip, red phosphor is mixed into the first non-conductive material, and green phosphor and blue phosphor are mixed into the second non-conductive material.
